(19) United States
(12) Patent Application Publication
(10) Pub. No.: US 2025/0299427 A1
(43) Pub. Date: Sep. 25, 2025

(54) DESIGNING DEVICE, AND METHOD FOR PROVIDING A 3D MODEL FOR A DESIGN DEVELOPMENT PROCESS OF AN OBJECT

(71) Applicant: AUDI AG, Ingolstadt (DE)

(72) Inventors: Sebastian HERBST, Manching (DE); Vladislav ROSOV, München (DE); Daniele SIRIGATTI, Ingolstadt (DE)

(73) Assignee: AUDI AG, Ingolstadt (DE)

(21) Appl. No.: 18/861,322

(22) PCT Filed: Jun. 13, 2023
(86) PCT No.: PCT/EP2023/065791

§ 371 Date: Oct. 29, 2024

(30) Foreign Application Priority Data
Jul. 12, 2022 (DE) 10 2022 117 313.5

(51) Int. Cl. G06T 15/20; G06F 30/27

(52) U.S. Cl. CPC G06T 15/20; G06F 30/27

(57) ABSTRACT

A design device and a method for providing a 3D model for a design development of an object. The method includes specifying an object type to a trained artificial neural network. the artificial neural network is trained with a plurality of basic image data of objects of this object type; generating an image data set of the predetermined object type by the trained artificial neural network, the artificial neural network provides image data from a plurality of perspectives as an image data set; checking the generated image data set for the presence of a design selection criterion, if the design selection criterion is not met, image data are regenerated by a change in an image property criterion; generating a digital 3D model from the image data set.

### FIELD

The invention relates to a method for providing a 3D model for a design development of an object. The invention further relates to a design device which is designed to carry out the method.

### BACKGROUND

The creation of a 3D CAD geometry is an important milestone in the design process phase, in order to get a feeling about the correct proportions, technical boundary conditions and the product/object in general. So far a 3D geometry is generated based on 2D sketches or photos by a designer using CAD (computer aided design) software. The creation of these 3D geometries is improved by passing through several design reviews with engineering and design teams until a certain technical and design maturity is achieved. Typically, 2D sketches are created, often comprising multiple adjustments for each of the 2D sketches. Then, based on the 2D sketches, a 3D model is created using CAD, wherein based on the 3D model, renderings are generated for the decision makers, which often requires several iterations.

This approach has several disadvantages, in that especially with 2D sketches multiple sketches per perspective are necessary for a 3D object, and when changing the design, each perspective must be adjusted individually, which means that each incremental adjustment of the design results in multiple adjustments in the sketches. Furthermore, a media discontinuity occurs during the transition to the 3-dimensional model, which is based on the 2D sketches, wherein the creation of the 3D models usually has to be carried out by persons skilled in the art. Here, too, an incremental adaptation of the design results in a manually complex adaptation of the 3D model and a complex communication between designers and CAD specialists is necessary, since a 2D sketch often does not contain enough information to correctly describe a 3D model and consequently to create it.

### SUMMARY

Therefore, the object of the invention is to simplify and/or accelerate a design development of an object.

The invention provides a method for providing a 3D model for a design development of an object. The method comprises the following steps, which can preferably be carried out by a computing device, in particular a processor and/or microchip. The method comprises specifying an object type for or on at least one trained artificial neural network, wherein the at least one artificial neural network is trained with a plurality of basic image data of objects of said object type. This means that initially an object type can be specified by which a type of the object to be designed is determined. For example, the object type of a computing device or a computer program can be predetermined, which is designed to carry out the method. The object type can be used, for example, to define for the program whether a motor vehicle component, such as, for example, a bodywork, rims, an interior component and/or components in other areas outside automotive technology, is to be produced as an object. The object type can be input to the computer program or the trained artificial neural network, for example, with the aid of a graphical user interface (GUI).

The at least one artificial neural network can comprise, for example, generative adversarial networks (GAN). An artificial neural network, often referred to as an artificial neural network, is a network of artificial neurons used for machine learning and artificial intelligence. Computer-based solutions can be found using an artificial neural network to solve various problems. Ultimately, an artificial neural network is an algorithm, this can be used to interpret various data sources, such as image data, and extract information or patterns from them, in order to apply the extracted information or patterns to previously unknown data. Ultimately, data-driven predictions can be produced, so that, for example, artificial data is generated, which is generated based on training data by the artificial neural network. The artificial neural network can be trained with image data, in particular with basic image data of objects of the predetermined object type.

In other words, the basic image data can be training data for the artificial neural network which originate from a plurality of objects of the same object type. For example, the object for which a new design is to be developed can be a motor vehicle, wherein for the design development of the motor vehicle an object type can be predetermined, which is to be designed by the method, for example a vehicle body or rims of the motor vehicle. Consequently, the artificial neural network can then preferably be trained with basic image data from different vehicle bodies or rims, in particular from a plurality of different motor vehicles. These basic image data can thus comprise a set of a plurality of images, wherein the individual images each comprise different embodiments of the object type. For example, it can be provided that a training process is connected upstream of the described method step, in which the GAN is trained starting from a data set of basic image data of real or artificial objects of the object type. By applying the GAN, the artificial intelligence can then generate new images based on image properties of the basic image data.

As a further method step, an image data set of the predetermined object type is generated by the artificial neural network which has been trained, wherein the artificial neural network provides an image data set of image data of the object type from a plurality of different perspectives which are determined from the training basic image data.

In other words, the trained artificial neural network can create new image data based on the acquired basic image data, in particular for multiple different perspectives or views of the object of the predetermined object type. In this case, the artificial neural network which has been trained with basic image data of the same object type can be selected, in order to thereby generate the artificial image data in the respective different perspectives of the object, wherein image data means 2D views from the different perspectives.

In a next step, the generated image data set can be tested for the presence of a design selection criterion, wherein image data of one or more perspectives are newly generated by means of a change in an image property criterion if the design selection criterion is not present. The design selection criterion can include, for example, whether image properties match or are consistent with one another in the respective perspectives of the image data. For example, if there were a color difference between two perspectives, it would be an inconsistency, wherein in that case the design selection criterion would not be fulfilled. In the example of the vehicle body, for example, it may happen that different model types are represented, for example a sedan in one perspective and a station wagon in another perspective, which would correspond to an inconsistency and thus the design selection criterion would not be fulfilled. Alternatively or in addition, the design selection criterion can also depend on a designer's stylistic perception, i.e. it could be an aesthetic criterion. In this case, the designer can manually approve or reject the image data, for example.

If the design selection criterion is not present, the image data of one or more perspectives can be newly generated by the artificial neural network by changing an image property criterion. In this case, the image property criterion can have a rule, an algorithm, data and/or information on the basis of which the image data can be changed. In particular, a plurality of the generated image data of a perspective can be newly generated by changing the image property criterion by means of an interpolation and/or recombination of image properties or partial image data of the generated image data. For example, when a GAN is used, one or more latent vectors can be changed in order to change the image data from at least one perspective.

In the interpolation, an interpolation between at least two provided image data of the image data set is preferably carried out. Preferably, a special embodiment of the GAN is used, namely a style-based GAN. The first artificial neural network of the style-based GAN is used mathematically to map random vectors in an intermediate latent space. For this purpose, it is possible, for example, to interpolate linearly between two or more latent vectors of the image data set which are each assigned to one of the at least two image data provided. In this case, a further latent vector is calculated, which is assigned to further image data which differ from the at least two image data provided, wherein this further latent vector is assigned to image data which lie between the two latent vectors provided of the image data set. Mathematically, during interpolation, a straight line running through the image data set, which can be understood as a type of image data space or latent image space, is generated, which connects the two image data provided. Each location on this straight line in turn represents further image data arranged at this location in the image data set. During interpolation, further image data are thus provided which can be taken from the image data set.

It can be achieved by means of the interpolation that a weighted average value is generated between the at least two image data provided. For example, 70 percent information, in particular design properties, of one image data of the at least two image data provided can be acquired, whereas only 30 percent information of the other image data of the image data provided are acquired. The combination of these respective information then leads to the further image data which differs from the image data provided. Ultimately, the interpolation can produce any desired combination of provided image data and/or a combination of the provided image data selected by a user by means of a corresponding change in the latent vectors in the form of new image data.

The recombination is based on the knowledge that the image data respectively describe different image properties which are each described by partial image data of the image data. For example, the image data provided can have up to 18 image properties. The image properties can be understood as different information levels or levels of the image data. The image properties can be referred to as abstract features. Individual or multiple image properties can, for example, at least partially describe and/or determine the number of spokes of a rim, a color design of the rim and/or the shape of the spokes of the rim.

In the recombination, it can be decided, for example, that certain first image properties of the image data are to be acquired, whereas second image properties deviating therefrom are to be acquired from other image data. In this way, for example, a coloring of a spoke can be acquired from the first-mentioned image data and a number of the individual spokes of the rim can be acquired from the second-mentioned image data for the generation of new image data. Thus, during the recombination, the respectively selected image properties of the respectively provided image data can be combined with one another.

In other words, the recombination is based on the image properties of the image data being generated at different levels in the artificial neural network. In the case of the GAN, these are generated by the so-called generator of the GAN. The generator is the artificial neural network of the GAN which, after a training process with the basic image data, generates artificial image data, for example of rims, i.e. generates the image data set. Preferably, during the training process of the generator for a given object type or a given object style, for example a given rim style, mathematically speaking, several latent vectors are always used, preferably on all levels of the generator. In an exemplary case of the training process in which, for reasons of clarity, only two latent vectors are described, it is possible, for example, to assign a first latent vector to levels 1 to k, a second vector being assigned to levels k+1 to n, wherein n describes a maximum number of levels. In case of application of the trained artificial neural network, a different latent vector can be used at each level. With preferably up to 18 such levels in the generator, there is a multiplicity of possible, respectively different combinations of image properties. Preferably, during the recombination, a plurality different provided image data are combined with one another, and thus the trained generator has multiple different latent vectors, in particular up to n different levels, wherein n describes a number of levels in the trained generator. Ultimately, this can be used to generate one or more new image data with combinations of image properties that best match a designer's personal ideas, for example.

The image properties which are adapted by the change in the latent vectors can preferably be known, as a result of which image properties of the image data can be regenerated or redesigned in a targeted manner. For example, shapes, proportions, colors and/or individual details in the respective image data can thus be changed in a targeted manner.

If the design selection criterion is present, a digital 3D model can then be generated from the image data set by a reconstruction algorithm, wherein the reconstruction algorithm calculates the digital 3D model from the image data of the plurality of different perspectives. Preferably, the plurality of different perspectives can be predetermined to enable the calculation of the 3D model for the reconstruction algorithm. The number of perspectives required can be object-dependent, wherein at least two perspectives, preferably 5 to 10 perspectives, are used from different angles on the object. For the reconstruction of the digital 3D model from the image data set, which comprises 2D views of the object, known reconstruction techniques can be used, which can be based in particular on neural networks and/or photogrammetry and/or differentiable rendering.

Finally, the generated 3D digital model can be provided as a design development for the object. The digital 3D model can be made available, for example, to a CAD program for further development of the object, for example the vehicle. Particularly preferably, the digital 3D model can be provided to a production system which generates a real 3D model from the digital 3D model, wherein the production system can in this case be a 3D printer and/or the digital 3D model can be provided to a production system, for example a production line for vehicle bodies, in order to produce the object according to the template of the digital 3D model.

The invention has the advantage that the design development is accelerated and can be carried out in a targeted manner. New designs can be quickly derived, reducing the time required for design development. It also enables rapid iterations and enhancements of existing designs and allows for targeted adaptation to an existing branding or different design languages of a brand. In addition, no media transitions, i.e. no change from, for example, paper drawings to digital object representations, are required. Ultimately, an abstract, but nevertheless targeted interpolation and/or recombination of artificial basic image data, which is, for example, predetermined by the designer, is made possible in order to obtain, simply and quickly, a control over designs and 3D geometries and style directions, which are often very complex or not possible with established CAD/CAS approaches.

The invention also comprises embodiments which result in additional advantages.

One embodiment provides that multiple artificial neural networks are provided, wherein a respective artificial neural network is trained for a predetermined perspective on the object by means of basic image data of objects of this object type based on this perspective. In a corresponding manner, the respective artificial neural network for generating the image data set can then generate only the image data of the respectively acquired perspective. In other words, a plurality of trained neural networks can be trained for a respective 2D view, wherein the basic image data used for training are provided for the respective neural network from the same perspective. Thus, each of these trained neural networks also produces only one 2D view from said perspective, wherein all trained neural networks provide the plurality of perspectives which can subsequently be used for the reconstruction of the 3D model. For example, the artificial neural networks can be generative models, in particular StyleGAN 2 or SWAGAN. This results in the advantage that a preferred embodiment for generating the image data from a plurality of perspectives can be provided.

A further embodiment provides that the at least one artificial neural network is trained by means of respective 2D views of 3D objects of one object type, wherein the 2D views are provided from a plurality of predetermined perspectives on the respective 3D object. In other words, the artificial neural network is trained with 3D objects, wherein the respective 3D object can be rotated into multiple predetermined perspectives and then the resulting 2D view is used for training. For example, real or digital 3D objects or models can be used, which are in particular digitally rotated into the different perspectives. For example, the 3D object for training the artificial neural network can be in a CAD tool that then rotates the 3D object into predetermined perspectives to provide 2D views for training. Thus, the artificial neural network can learn the 2D representations of 3D objects and then generate new image data from these acquired 2D views when generating the image data set. Alternatively, a data set of basic image data of the 3D object, which is heterogeneous in terms of the perspectives, can be used to train the at least one artificial neural network. Style-NERF, for example, can be used as an artificial neural network. This embodiment has the advantage that the neural network can already be trained with consistent basic image data of a 3D object and thus inconsistencies in the generation of new image data can be reduced.

It is preferably provided that the design selection criterion is present at least if an image property is consistent in the plurality of perspectives of the image data. In particular, it can be checked whether the image property of the image data is the same in the plurality of different perspectives or whether, for example, there is a break in style, in particular non-contiguous shapes between the different perspectives. For example, in the case of a vehicle body, it can be checked whether a station wagon is represented in one perspective and a sedan in another perspective, in which case the design selection criterion would not be fulfilled. The design selection criterion can preferably be checked automatically, in particular by means of a further neural network which examines the generated image data in this respect. Alternatively, or in addition, the design selection criterion can be verified by a designer who can approve the image data set. This has the advantage that the design development of an object can be further simplified.

A further embodiment provides that a generative adversarial network (GAN) is used as the artificial neural network. The generating generic network can alternatively be described as a kind of generative deep neural network. GAN is an algorithmic architecture that uses two artificial neural networks. The two artificial neural networks ultimately serve to generate synthetic, that is artificial, new data sets, in particular image data sets.

The one artificial neural network of the GAN is called the generator and creates the image data set. The other artificial neural network of the GAN is called a discriminator and evaluates the generated image data of the image data set. Typically, the generator, in mathematical terms, maps a vector of latent variables to a desired result space. During training, the generator learns to generate the image data of the image data set according to a predetermined distribution. The discriminator is trained to distinguish these results of the generator from data from the predetermined distribution. The predetermined distribution here is the basic image data. At the end of the training, the generator is designed to generate image data which the discriminator cannot distinguish from the basic image data. The generated distribution, i.e. the generated image data set, is thereby to be gradually adjusted to a true distribution, i.e., for example, have realistic images of objects, such as a vehicle body.

Preferably, a special embodiment of the GAN is used, namely a style-based GAN, such as, for example, a StyleGAN 1, StyleGAN 2 and/or a SWAGAN (Style and Wavelet Based GAN). The first artificial neural network of the style-based GAN which is designed as a StyleGAN 1, for example, is used mathematically to map random vectors in an intermediate latent space. A data output of the first artificial neural network is, for example, fed to the second artificial neural network at different adaptive instance normalization layers (AdaIN for Adaptive Instance Normalization) and is controlled so that the image data generated by the second neural network are configured as realistic image data of the object. Alternatively or in addition to this, the data output of the first artificial neural network can be supplied to the second artificial neural network at similarly functioning layers. The similarly functioning layers are, for example in the case of StyleGAN 2, so-called demodulations and/or modulations. The second neural network can be called a synthesizing network. The generation and thus the creation of image data by the synthesis network takes place in stages, wherein an image resolution starts at 4×4 pixels and is gradually refined by means of the artificial neural network. The latent vectors are used as style vectors at different levels. The number of layers is up to 18 layers depending on the desired size of the generated image data. At the end, for example, a portable network graphic (Png image file) is output. The influence of a particular style vector or latent vector on the generated image data depends, inter alia, on the selected depth of the respective AdaIN layer.

The image data generated by the generator has the image properties, wherein the image properties can be referred to as styles when using the style-based GAN. The image properties associated with the first levels are preferably responsible for global properties of the imaged object. The image properties associated with the lower levels preferably determine local properties of the object, such as a color scheme. Depending on the resolution selected, the synthesizing network can control image data with up to 18 style vectors, i.e. 18 image properties. The sequenced style vectors can also be referred to as DNA vectors.

The prerequisite for successful training of the style-based GAN is the basic image data, which is used for training. Here, the basic image data preferably comprise a large variety of configurations of the object. Preferably, the basic image data can additionally be evaluated via a main component analysis PCA (Principal Component Analysis) in the Fourier space. The results of this evaluation are converted into a two-dimensional image space by means of T-distributed stochastic neighbor embedding (T-SNE). As a result, particularly similar image data can be identified at an early stage and, for example, sorted out.

Based on methods of artificial intelligence, the training of the GAN, in particular the style-based GAN, with a basic image data set suitable for the desired object thus achieves reliable, realistic new image data of the object and thus a suitable image data set is provided for the method.

A further embodiment provides for the image data of one or more perspectives to be regenerated by means of a change in the image property criterion, in that the image data are interpolated and/or recombined. In other words, in each case at least two different image data can be used to generate the new and changed image data set in order to carry out a variation of the respective individual image data provided. Preferably, a plurality of image data for each perspective can first be generated by the trained artificial neural network, wherein image properties of two or more of the respective image data of a respective perspective can be regenerated by interpolation and/or recombination by changing the image property criterion, whereby completely new image data can be generated. The mode of operation of the GAN for interpolation and recombination is already described above. Thus, starting from the image data set generated with the aid of the at least one artificial neural network, combined image data can be generated by selecting the at least two image data and interpolating and/or recombining them as new image data. The combined image data preferably describe an image of an object redesigned by the artificial neural network, that is to say of an object not previously known to at least the artificial neural network. Alternatively, the latent vectors can be randomly modified in latent space to generate new image data. This embodiment has the advantage that a targeted variation of the image properties can be carried out and thus a fine adjustment of the design development is made possible.

It is preferably provided that the image property criterion is changed by means of an adaptation of latent vectors. In other words, the image property criterion is defined by the latent vectors. In this case, the latent vectors can access different levels of the acquired basic image data and thus have image properties which the generated image data are intended to have for the image data set. In particular, it is thus possible, for example for a designer, to change an image property in a targeted manner in one or more image data of different perspectives without having to produce completely new 2D sketches in a complicated manner. Preferably, the change of the latent vectors can be carried out by means of a graphical user interface in which the dependencies of the latent vectors are provided. This means that the graphic user interface can be used to know which image property is adapted by changing the respective latent vector. In particular, the designer can move a point in the latent space described by the latent vectors along a main component, thus changing the expression of specific properties of the object. This results in the advantage that image data can be adapted in a simple manner.

It is preferably provided that image properties which are adapted by changing the image property criterion comprise the following: a dimension of the object, that is to say, for example, dimensions or a size of the object; proportions of the object, a stylistic direction of the object; a color of the object and/or shapes of individual details of the object. These can be adapted, for example, by means of the latent vectors described above, in that different levels of the basic images are controlled.

A further embodiment provides for the object and/or a real 3D model to be generated from the digital 3D model provided, in particular by means of a production system. This means that the data from the digital 3D model can be used to control a manufacturing system that generates a real object. Preferably, the production system can automatically produce the object by means of the data or information of the digital 3D model, i.e. without additional manual work steps. The production system can be based, for example, on an additive production method, in particular comprising a 3D printer or a photolithographic system. Alternatively or additionally, the production system can comprise an injection molding machine or be the injection molding machine. Thus, for example, a prototype can be produced which is based on the digital 3D model provided by the method. It is finally possible to produce objects of different designs, such as a vehicle body or a rim for a motor vehicle, simply and inexpensively. Thus, the method according to the invention can support an entire production process of the object from a design development to the production of the newly designed object.

A further aspect of the invention relates to a design device which is designed to carry out a method according to one of the preceding embodiments. For example, the design device can comprise a computing device, in particular a computer, on which the at least one artificial neural network can be operated. Preferably, this can be controlled via a graphical user interface and have at least one screen in which individual steps of the method can be monitored and/or the digital 3D model provided can be displayed. The design device can also comprise a production system to which the digital 3D model is transmitted and which can subsequently produce a real 3D model. This results in the same advantages and possibilities for variation regarding the method.

For applications or usage situations that can arise in the method and which are not explicitly described here, it can be provided according to the method, that a fault message and/or a request for input of user feedback is output and/or a standard setting and/or a predetermined initial status are set.

The invention also includes a control device for the design device. The control device can comprise a data processing device or a processor device which is configured to carry out an embodiment of the method according to the invention. For this purpose, the processor device can have at least one microprocessor and/or at least one microcontroller and/or at least one FPGA (Field Programmable Gate Array) and/or at least one DSP (Digital Signal Processor). Furthermore, the processor device can have program code which is configured to carry out the embodiment of the method according to the invention when it is executed by the processor device. The program code can be stored in a data memory of the processor device. Alternatively or additionally, the method, which can be present as program code, can be provided by a computer cloud (cloud computing).

The invention also includes refinements of the device according to the invention, which have features as have already been described in conjunction with the refinements of the method according to the invention. For this reason, the corresponding developments of the design device according to the invention are not described again here.

Preferably, the method can be used to produce a model of a motor vehicle component, in particular for a passenger car, truck, passenger bus and/or a motorcycle.

As a further solution, the invention also comprises a computer-readable storage medium, comprising instructions which, when executed by a computer or a computer network, cause it to execute an embodiment of the method according to the invention. The storage medium can be formed, for example, at least partially by a non-volatile data memory (such as a flash memory and/or as an SSD—solid state drive) and/or at least partially as a volatile data memory (such as a RAM—random access memory). A processor circuit with at least one microprocessor can be provided by the computer or computer network. The commands can be provided as binary code or assembler and/or as source code of a programming language (such as C).

The invention also comprises the combinations of the features of the described embodiments. The invention therefore also comprises implementations which each have a combination of the features of several of the described embodiments, unless the embodiments have been described as mutually exclusive.

### BRIEF DESCRIPTION OF THE FIGURES

Exemplary embodiments of the invention are described hereinafter. In particular:

FIG. 1 shows a schematically illustrated design device according to an exemplary embodiment;

FIG. 2 shows a schematic method diagram according to an exemplary embodiment.

### DETAILED DESCRIPTION

The exemplary embodiments explained below are preferred embodiments of the invention. In the exemplary embodiments, the described components of the embodiments each represent individual features of the invention to be considered independently of one another, which each also develop the invention independently of one another. Therefore, the disclosure is also predetermined to comprise combinations of the features of the embodiments other than those represented. Furthermore, the described embodiments can also be supplemented by further ones of the above-described features of the invention.

In the figures, same reference numerals respectively designate elements that have the same function.

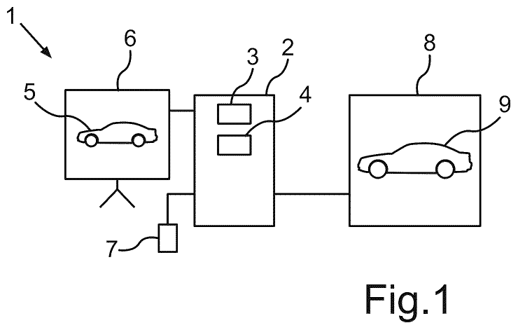

In FIG. 1, a design device 1 is sketched, which can be configured for carrying out a method for providing a 3D model for a design development of an object. The design device 1 can comprise a computing device 2, in particular a computer, which has a processor device 3 and a storage medium 4. Thus, program code for at least one artificial neural network and/or basic image data of objects can be stored on the storage medium 4, which is, for example, a hard disk of the computer, wherein the processor device 3 can be designed to execute the program code of the artificial neural network in order to generate a digital 3D model 5 of an object, wherein the object in this example can be a motor vehicle. Alternatively, the processor device 3 can be provided, for example, in a cloud.

The computing device 2 can be provided with a display device 6 for displaying the digital 3D model 5, wherein a method for providing the digital 3D model 5 can be monitored and/or adapted via the display device 6, preferably via a graphical user interface. In particular, the design device 1 can comprise input devices 7 by means of which settings, in particular on the graphical user interface, can be changed. The input devices may comprise, for example, a computer keyboard, a computer mouse and/or touch-sensitive input fields.

The design device 1 preferably additionally comprises a production system 8 which can be designed as an additive production system 8, for example as a 3D printer or as a photolithographic system. In particular, the production system 8 can be designed to convert the digital 3D model 5 into a real 3D model 9, i.e. in this example a real model of the motor vehicle.

The respective data can be transmitted via cable and/or wirelessly between the individual devices of the design device 1, in particular between the computing device 2, the display device 6 and/or the production system 8.

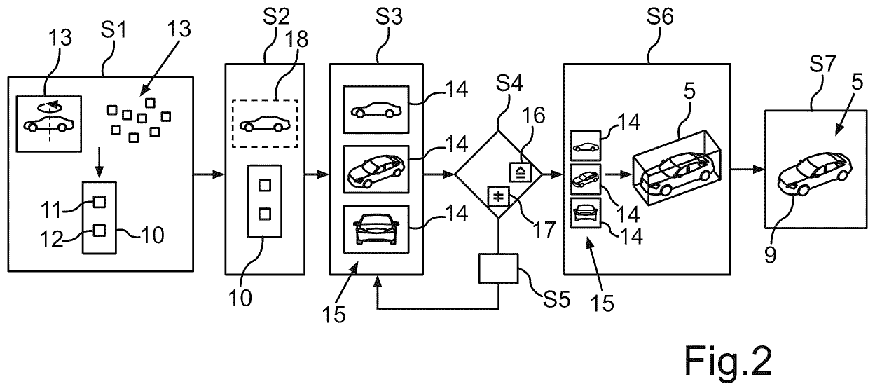

FIG. 2 shows a method for providing a 3D model 5 of an object according to an exemplary embodiment. In a first method step S1, an artificial neural network 10 can be trained, the artificial neural network 10 preferably being a generative adversarial network, a so-called GAN (generative adversarial network). Such a GAN 10 comprises two artificial neural networks 11, 12, of which a first network is designated as generator 11 and a second network is designated as discriminator 12. The GAN 10 can either be trained with a plurality of basic image data 13 of an object, the basic image data preferably being made available from different perspectives on the object and a separate GAN 10 being trained for each of these perspectives. A so-called StyleGAN 2, SWAGAN or StyleNERF, for example, is suitable here. Alternatively, a 3D object can be provided as the basic image data 13, which can be rotated into a plurality of different 2D views and thus predetermined perspectives on the respective 3D object are provided. In this example, the basic image data can be a vehicle body. However, other object types can also be acquired by means of corresponding basic image data.

In a method step S2, an object type 18 for which the GAN 10 is to generate images can be set for the trained GAN 10, the GAN 10 preferably having previously been trained for the preset object type 18 by means of the basic image data 13 of the object type 18. In this example, it can thus be specified as object type 18 that a vehicle body is to be provided as a design development.

In a step S3, the GAN 10 can generate an image data set 15 of the predetermined object type 18, for which purpose the trained GAN 10 interpolates and/or recombines image features which are acquired from the basic image data 13 or training data in order to generate new image data 14 of the object type 18, in particular image data 14 for a plurality of different perspectives of the object.

In a step S4, the generated image data set 15 can be checked for whether a design selection criterion is met 16 or the design selection criterion is not met 17, wherein the design selection criterion can be, for example, whether an image property is consistent in the image data 14 or not. For example, it can be checked whether a color of the body is consistent in the respective perspectives and/or whether shapes fit together. It is also possible, for example, for a designer to check whether a style corresponds to her ideas or whether the image data 14 is to be changed. If this is the case and the design selection criterion is not met 17, one or more perspectives can be regenerated by the GAN 10 in a step S5 by changing an image property criterion. In this case, in particular one or more latent vectors can be adapted, which control different levels of the basic image data and can thus change, in particular, a dimension, proportions, a stylistic direction, a color and/or shapes of individual details. For this purpose, by changing the image property criterion, image properties of the image data which can be present for each perspective are preferably interpolated and/or recombined in order to adapt the image properties in a targeted manner. Consequently, for example, a designer can create completely new image data 14 or can modify only individual image properties of the image data 14 in one or more perspectives in order to arrive at a new image data set 15. The image data 14 of the image data set 15 provide 2D views from the different perspectives, which can be displayed and checked, for example, by the display device 6.

If the image data are consistent and the designer is satisfied with the representations of the image data 14 in the various perspectives, the design selection criterion can be met 16 and the digital 3D model 5 can then be calculated in a step S6 by means of a reconstruction algorithm. The reconstruction algorithm can be, for example, a further neural network which creates the 3D model 5 from the views of the image data 14 and/or can be calculated back to the 3D model 5 using methods of photogrammetry and/or differentiable rendering.

Finally, in a step S7, the generated digital 3D model 5 can be made available as a design development for the object, in this case the vehicle body, wherein preferably a production system 8 can generate a real 3D model 9, for example a model made of plastic, which is generated by a 3D printer.

Overall, the examples show how a GAN-based generation of 3D geometries can be achieved by the invention.

1-10. (canceled)

11. A method of providing a 3D model for design development of an object, by performing the method on a computing device, comprising:
specifying an object type for at least one trained artificial neural network, wherein the at least one artificial neural network is trained with a plurality of basic image data of objects of this object type;
generating an image data set of the predetermined object type by the trained artificial neural network, wherein the artificial neural network provides an image data set of image data of the object type from a plurality of different perspectives which are determined from the acquired basic image data, with which the artificial neural network was trained;
automatic checking the generated image data set by a further neural network for the presence of a design selection criterion, wherein if the design selection criterion is not met, image data of one or more perspectives are newly generated by a change of an image property criterion;
generating a digital 3D model from the image data set for which the design selection criterion is met by a reconstruction algorithm, wherein the computing device calculates, by the reconstruction algorithm, the digital 3D model from the image data of the plurality of different perspectives;
providing the generated digital 3D model as design development for the object,
wherein the object and/or a real 3D model is generated from the provided digital 3D model by a production system.

12. The method according to claim 11, wherein multiple artificial neural networks are provided, wherein a respective artificial neural network is trained for a predetermined perspective on said object for said perspective by basic image data of objects of said object type.

13. The method of claim 11, wherein the at least one artificial neural network is trained by respective 2D views of 3D objects of the object type, wherein the 2D views are provided from a plurality of predetermined perspectives on the respective 3D object.

14. The method according to claim 11, wherein the design selection criterion is met at least if an image property is consistent in the plurality of perspectives of the image data.

15. The method according to claim 11, wherein a generative adversarial network, GAN, is used as the artificial neural network.

16. The method according to claim 11, wherein the image data of one or more perspectives is regenerated by changing the image property criterion by interpolating and/or recombining the image data.

17. The method according to claim 11, wherein the image property criterion is varied by latent vector matching.

18. The method according to claim 11, wherein image properties adapted by changing the image property criterion comprise:
a dimension of the object;
proportions of the object;
a stylistic direction of the object;
a color of the object;
shapes of individual details of the object.

19. A design device for providing a 3D model for a design development of an object, wherein the design device comprises a computing device and a production system, wherein the computing device is configured to carry out a method according to claim 11.

20. The method according to claim 12, wherein the design selection criterion is met at least if an image property is consistent in the plurality of perspectives of the image data.

21. The method according to claim 13, wherein the design selection criterion is met at least if an image property is consistent in the plurality of perspectives of the image data.

22. The method according to claim 12, wherein a generative adversarial network, GAN, is used as the artificial neural network.

23. The method according to claim 13, wherein a generative adversarial network, GAN, is used as the artificial neural network.

24. The method according to claim 14, wherein a generative adversarial network, GAN, is used as the artificial neural network.

25. The method according to claim 12, wherein the image data of one or more perspectives is regenerated by changing the image property criterion by interpolating and/or recombining the image data.

26. The method according to claim 13, wherein the image data of one or more perspectives is regenerated by changing the image property criterion by interpolating and/or recombining the image data.

27. The method according to claim 14, wherein the image data of one or more perspectives is regenerated by changing the image property criterion by interpolating and/or recombining the image data.

28. The method according to claim 15, wherein the image data of one or more perspectives is regenerated by changing the image property criterion by interpolating and/or recombining the image data.

29. The method according to claim 12, wherein the image property criterion is varied by latent vector matching.

30. The method according to claim 13, wherein the image property criterion is varied by latent vector matching.
